(19) United States
(12) Patent Application Publication
(10) Pub. No.: US 2016/0104771 A1
(43) Pub. Date: Apr. 14, 2016

(54) COMMON CONTACT OF N++ AND P++ TRANSISTOR DRAIN REGIONS IN CMOS

(71) Applicant: Applied Materials, Inc., Santa Clara, CA (US)

(72) Inventor: Wolfgang R. ADERHOLD, Cupertino, CA (US)

(21) Appl. No.: 14/867,683

(22) Filed: Sep. 28, 2015

Related U.S. Application Data
(60) Provisional application No. 62/138,747, filed on Mar. 26, 2015.
(60) Provisional application No. 62/063,316, filed on Oct. 13, 2014.

(51) Int. Cl. H01L 29/08; H01L 21/8238; H01L 27/092

(52) U.S. Cl. CPC H01L 29/0847; H01L 27/092; H01L 21/823814

(57) ABSTRACT

Implementations of the present disclosure relate to semiconductor devices such as transistors used for amplifying or switching electronic signals. In one implementation, an integrated circuit is provided. The integrated circuit comprises a first transistor having a first conductivity type, the first transistor comprising a first gate, an first source region and a first drain region disposed on opposite sides of the first gate, and a second transistor having a second conductivity type opposite from the first conductivity type of the first transistor, the second transistor comprising a second gate, a second source region and a second drain region disposed on opposite sides of the second gate, wherein the second drain region of the second transistor is abutted against the first drain region of the first transistor.

### CROSS-REFERENCE TO RELATED APPLICATIONS

This application claims priority to U.S. provisional patent application Ser. Nos. 62/063,316, filed Oct. 13, 2014, and 62/138,747, filed Mar. 26, 2015, which are herein incorporated by reference.

### FIELD

Implementations of the present disclosure generally relate to circuit devices and fabrication of circuit devices.

### BACKGROUND

Microelectronic devices are fabricated on a semiconductor substrate as integrated circuits in which various conductive layers are interconnected with one another to permit electronic signals to propagate within the device. An example of such a device is a complementary metal-oxide-semiconductor (CMOS) field effect transistor (FET) or MOSFET. Typical MOSFET transistors may include p-channel (PMOS) transistors and n-channel MOS (NMOS) transistors, depending on the dopant conductivity types, whereas the PMOS has a p-type channel, i.e., holes are responsible for conduction in the channel, and the NMOS has an n-type channel, i.e., the electrons are responsible for conduction in the channel. In a CMOS transistor, for example, the semiconductor material is engineered to create a gate structure disposed between a source region and a drain region that are formed in the semiconductor material. The gate structure may include a gate electrode and a gate dielectric. The gate electrode is disposed over the gate dielectric to control a flow of charge carriers in a channel region that is formed between drain and source regions beneath the gate dielectric. The gate dielectric serves as an insulator to prevent large leakage currents from flowing into the channel region between the gate electrode and the channel region.

Semiconductor industry is in an era of transitioning from 2D transistors, which are often planar, to 3D transistors using a three-dimensional gate structure. In 3D gate structures, the channel, source and drain are raised out of the silicon substrate and the gate is wrapped around the channel on three sides. One such type of 3D transistors is known as FinFET (Fin field-effect transistor), in which the channel connecting the source and drain is a thin “fin” jutting out of the substrate. The gate controls a flow of charge carriers in the channel more strongly because it extends over three sides of the fin shaped channel, rather than only across the top of a more traditional planar channel. This results in the current being constrained to the raised channel, thereby preventing electrons from leaking.

However, there is a need in the art to provide a fabrication technique for transistors to improve the control capacity of the gate with respect to the channel.

### SUMMARY

Implementations of the present disclosure relate to methods of manufacturing semiconductor devices such as transistors used for amplifying or switching electronic signals. In one implementation, an integrated circuit is provided. The integrated circuit comprises a first transistor having a first conductivity type, the first transistor comprising a first gate, an first source region and a first drain region disposed on opposite sides of the first gate, and a second transistor having a second conductivity type opposite from the first conductivity type of the first transistor, the second transistor comprising a second gate, a second source region and a second drain region disposed on opposite sides of the second gate, wherein the second drain region of the second transistor is abutted against the first drain region of the first transistor.

In another implementation, the integrated circuit comprises a first transistor having a first conductivity type, the first transistor comprising a first gate, an first source region and a first drain region disposed on opposite sides of the first gate, a second transistor having a second conductivity type opposite from the first conductivity type of the first transistor, the second transistor comprising a second gate, a second source region and a second drain region disposed on opposite sides of the second gate, wherein the p-type drain region of the second transistor is abutted against the n-type drain region of the first transistor, and an output contact in electrical communication with the first drain region of the first transistor and the second drain region of the second transistor, wherein the first drain region of the first transistor and the second drain region of the second transistor each comprises a heavily doped region.

In yet another implementation, a method of forming an integrated circuit is provided. The method comprises forming a first transistor having a first conductivity type on a substrate, the first transistor comprising a first gate, an first source region and a first drain region disposed on opposite sides of the first gate, forming a second transistor having a second conductivity type opposite from the first conductivity type of the first transistor, the second transistor comprising a second gate, a second source region and a second drain region disposed on opposite sides of the second gate, wherein the second drain region of the second transistor is abutted against the first drain region of the first transistor, covering the second transistor and implanting dopants into the first drain region of the first transistor by tilting the substrate at an angle, activating implanted dopants in the first drain region, wherein the first drain region is heavily doped with dopants having the first conductivity type, covering the first transistor and implanting dopants into the second drain region of the second transistor by tilting the substrate at an angle, activating implanted dopants in the second drain region, wherein the second drain region is heavily doped with dopants having the second conductivity type, and forming an output contact layer over the first drain region of the first transistor and the second drain region of the second transistor, wherein the output contact is in electrical communication with the first drain region of the first transistor and the second drain region of the second transistor.

### BRIEF DESCRIPTION OF THE DRAWINGS

Implementations of the present disclosure, briefly summarized above and discussed in greater detail below, can be understood by reference to the illustrative implementations of the disclosure depicted in the appended drawings. It is to be noted, however, that the appended drawings illustrate only typical implementations of this disclosure and are therefore not to be considered limiting of its scope, for the present disclosure may admit to other equally effective implementations.

FIG. 1 depicts a flow chart of a method for manufacturing an integrated circuit according to implementations of the disclosure.

FIGS. 2A-2S depict perspective views of a simplified, conceptual integrated circuit during various stages of fabrication according to the flow chart of FIG. 1.

FIG. 3 illustrates a conceptual inverter fabricated to have a p-type drain of a p-type transistor connected directly and in physical contact with an n-type drain of an n-type transistor to according to implementations of the present disclosure.

FIG. 4 illustrates a conceptual NAND gate fabricated according to implementations of the present disclosure.

To facilitate understanding, identical reference numerals have been used, where possible, to designate identical elements that are common to the figures. The figures are not drawn to scale and may be simplified for clarity. It is contemplated that elements and features of one implementation may be beneficially incorporated in other implementations without further recitation.

### DETAILED DESCRIPTION

Implementations of the present disclosure provide methods for manufacturing semiconductor devices such as transistors used for amplifying or switching electronic signals. For example, the disclosed methods may be utilized in the manufacture of CMOS (Complementary Metal-Oxide-Semiconductor) transistors. While implementations described in this disclosure use a general term “integrated circuit” as an example, it should be understood that implementations or concepts of the present disclosure are equally applicable to any integrated circuit technologies such as bipolar, N-type or P-type metal oxide semiconductor (NMOS or PMOS), or CMOS etc. Particularly, implementations of the present disclosure can benefit processes of fabricating NMOS/PMOS inverters or gates, CMOS inverters or gates, any integral circuit devices incorporating a gate structure, or any integral circuit devices having transistors (2D or 3D) or multiple gate structures.

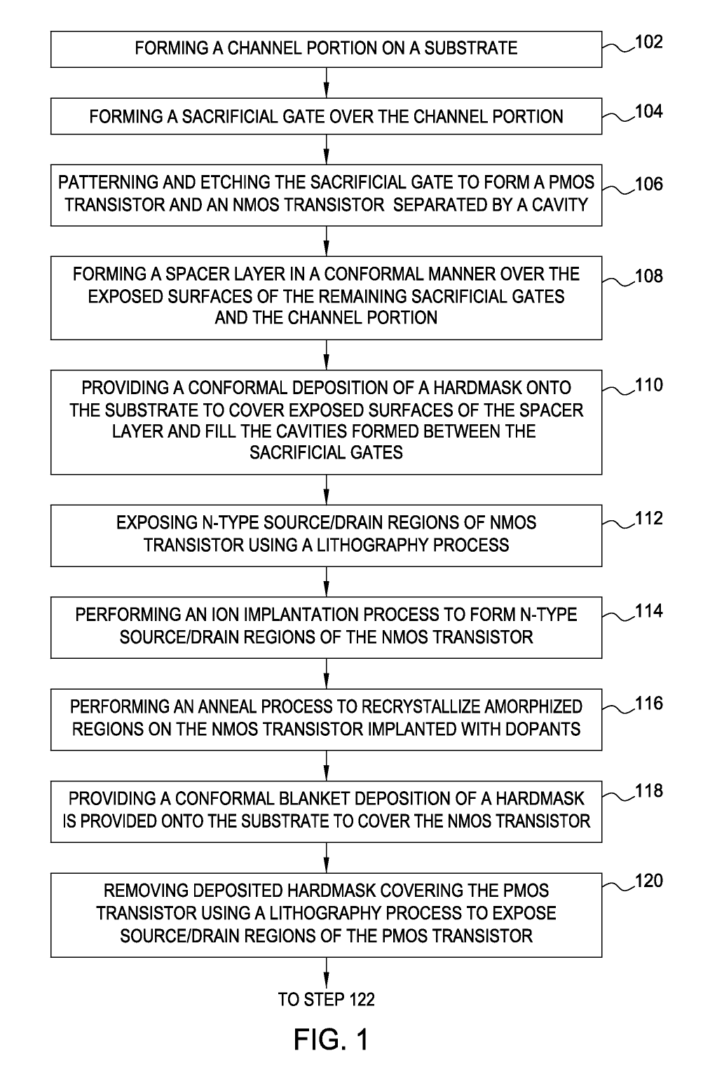

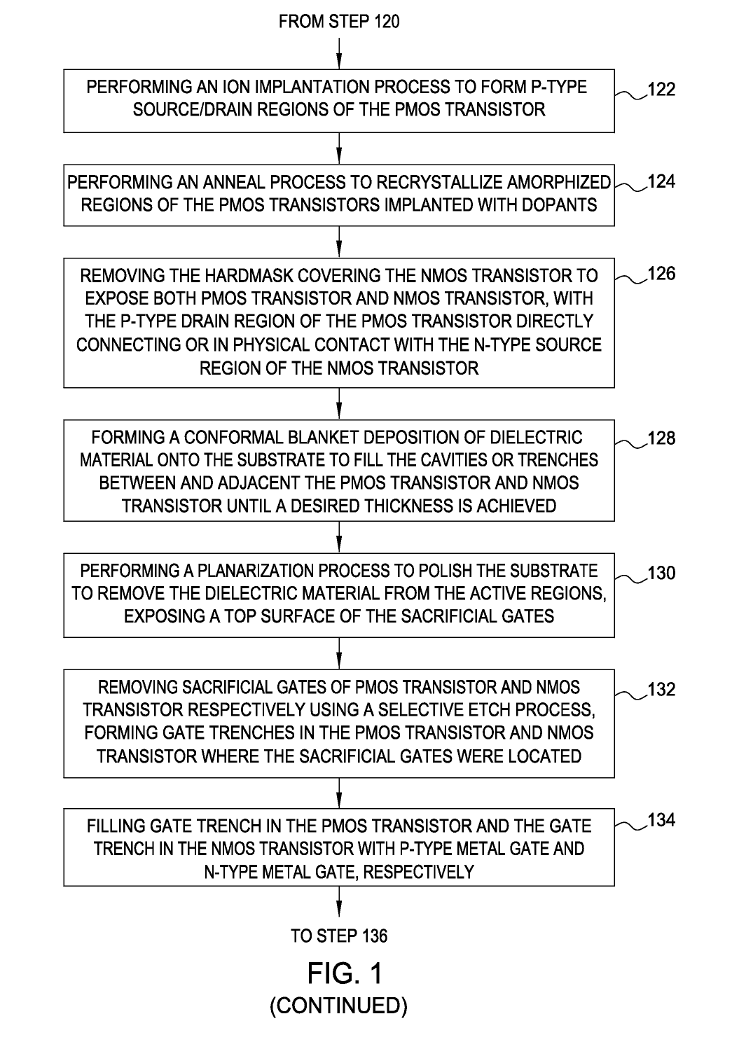

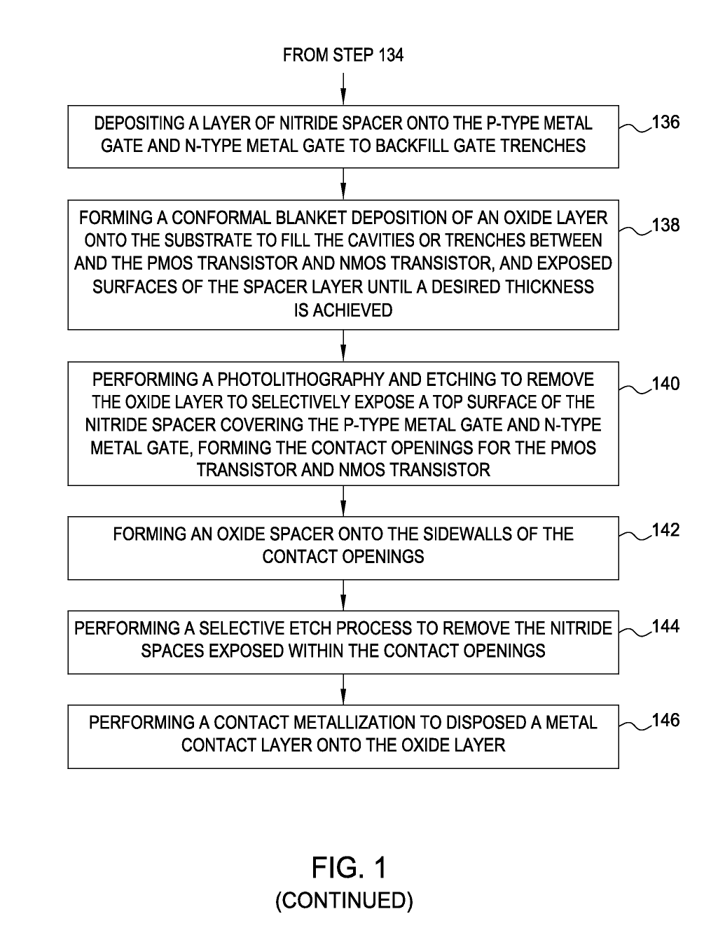

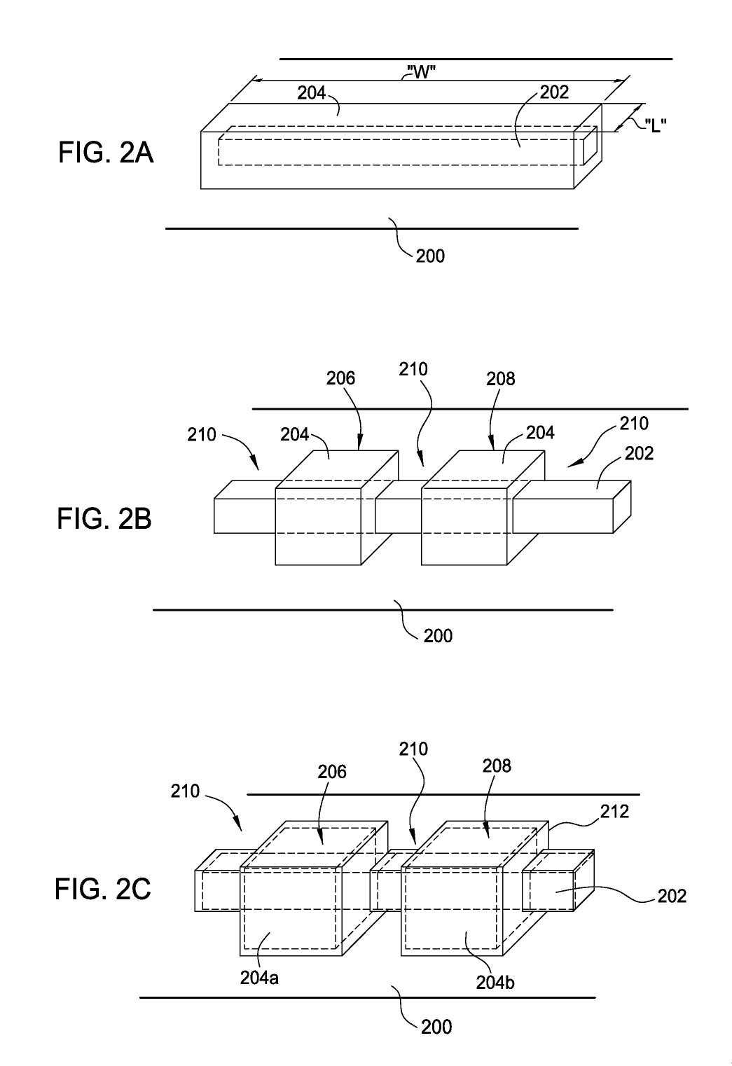

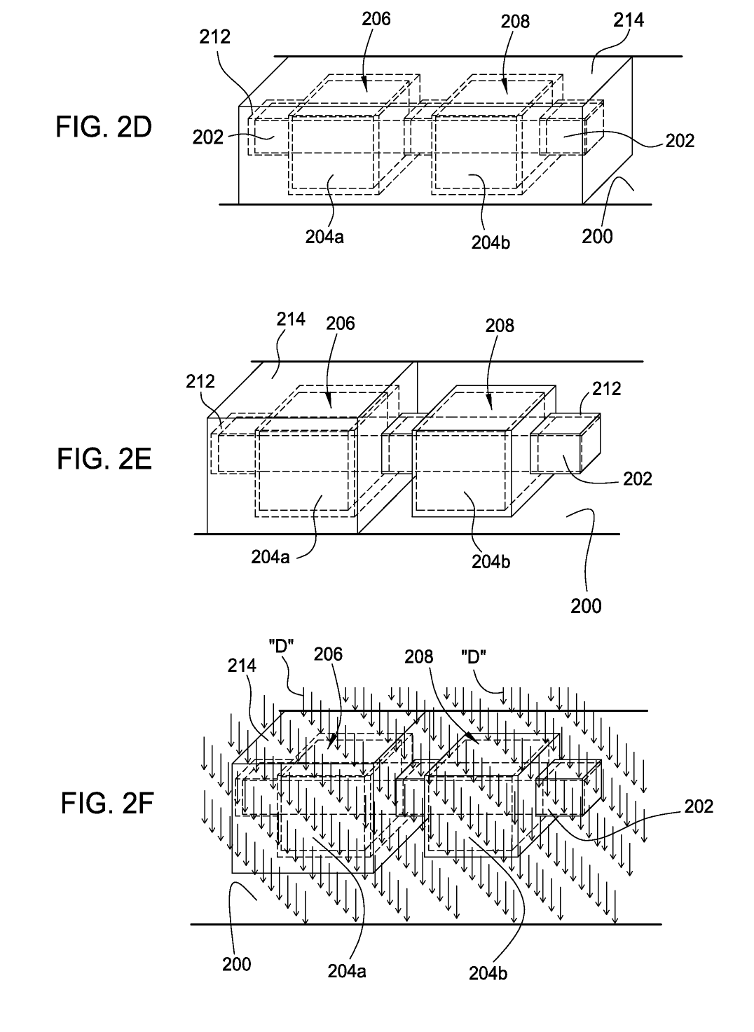

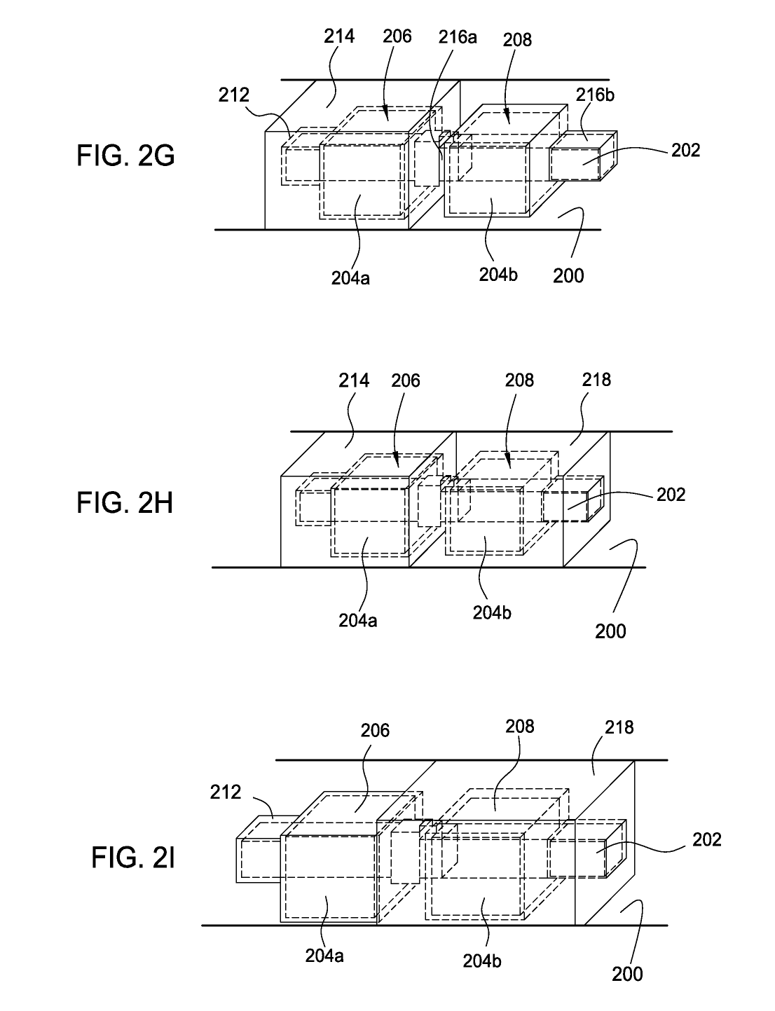

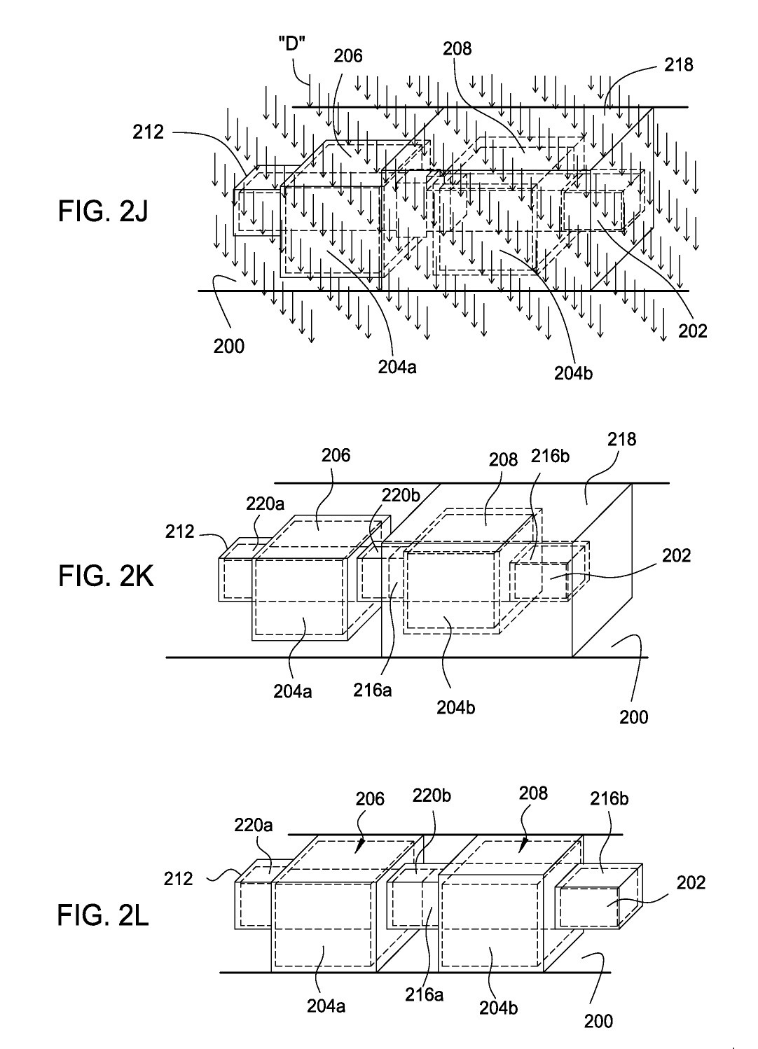

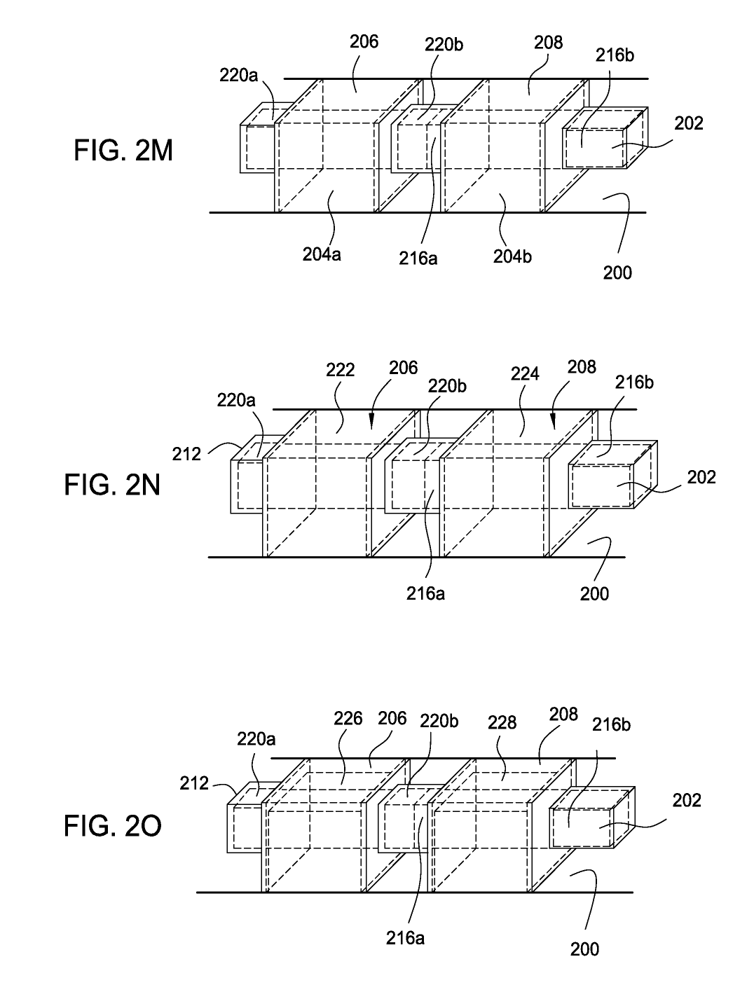

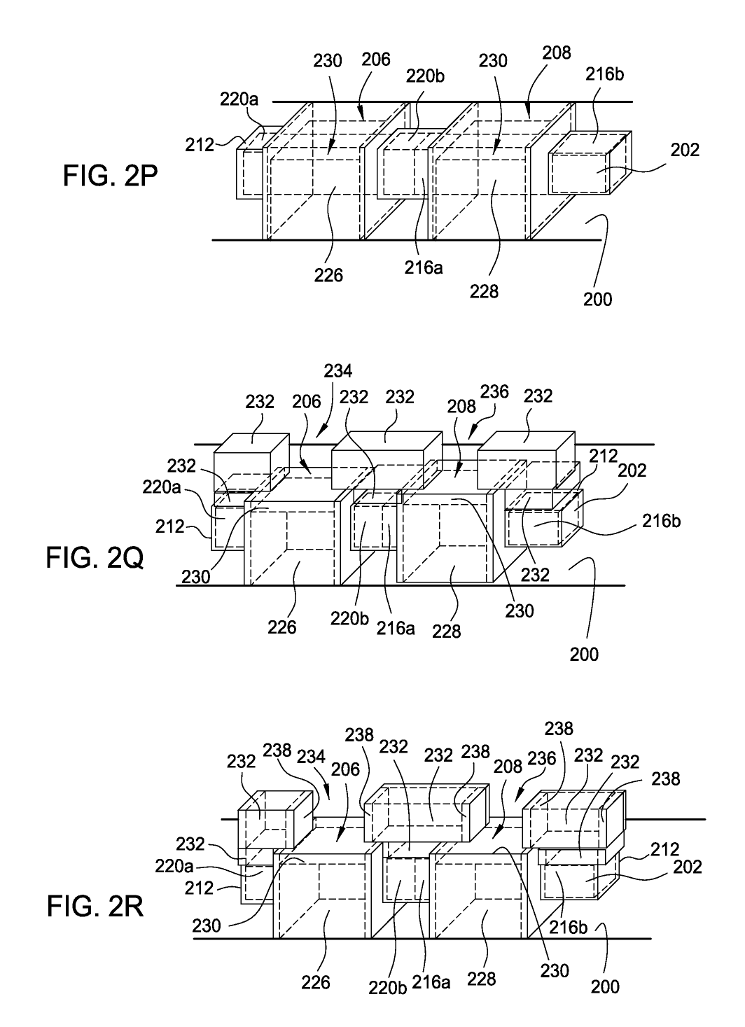

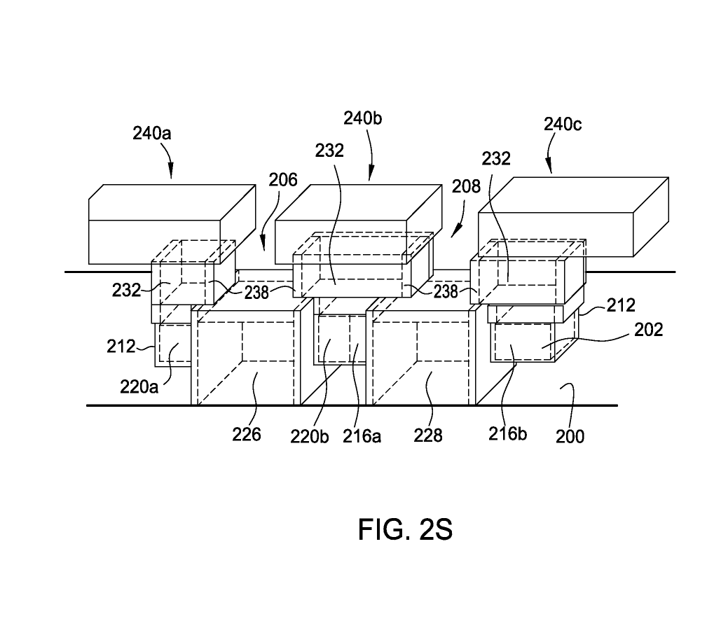

FIG. 1 depicts a flow chart of a method 100 for manufacturing an integrated circuit according to implementations of the disclosure. FIG. 1 is illustratively described with reference to FIGS. 2A-2S, which show perspective views of a simplified, conceptual integrated circuit during various stages of fabrication according to the flow chart of FIG. 1. Those skilled in the art will recognize that the structures FIGS. 2A-2S, while generally drawn to illustrate approximate relative sizes or dimensions for ease of understanding, are not drawn to scale. Those skilled in the art will further recognize that the full process for forming a transistor circuit and the associated structures are not illustrated in the drawings or described herein. Instead, for simplicity and clarity, only so much of a process for forming a transistor circuit and the associated structures as is unique to the present disclosure or necessary for an understanding of the present disclosure is depicted and described. In addition, although various steps are illustrated in the drawings and described herein, no limitation regarding the order of such steps or the presence or absence of intervening steps is implied. Steps depicted or described as sequential are, unless explicitly specified, merely done so for purposes of explanation without precluding the possibility that the respective steps are actually performed in concurrent or overlapping manner, at least partially if not entirely.

The method 100 begins at block 102 by forming a channel portion 202 on a substrate 200, as shown in FIG. 2A. In one implementation, the channel portion 202 may be formed of a monolithic silicon body that is patterned from a silicon layer provided on the substrate 200. The channel portion 202 may be formed from the same material as the substrate 200. Alternatively, the channel portion 202 may be formed of a group III-V semiconductor compound such as InAs, InGaAs, InGaSb, InP, InAlSb, GaSb, or the like. In some implementations, the channel portion 202 may be or include Ge or SiGe. Other materials such as group II-VI semiconductor compounds, binary compounds from Groups II-VI or Groups III-V, ternary compounds from Groups II-VI or Groups III-V, quaternary compounds from Groups II-VI or Groups III-V, or mixtures or combinations thereof, may also be used. In either case, the channel portion 202 is formed vertically protruding from the surface of the substrate 200. The channel portion 202 may have a thickness of about 1 nanometers (nm) to about 20 nm, for example about 5 nm.

The term “substrate” used herein is intended to broadly cover any object that can be processed in a process chamber. The substrate 200 may be any substrate capable of having material deposited thereon, such as a silicon substrate, for example silicon (doped or undoped), crystalline silicon (e.g., Si <100> or Si <111>), silicon oxide, strained silicon, doped or undoped polysilicon, or the like, germanium, a III-V compound substrate, a silicon germanium (SiGe) substrate, an epi substrate, a silicon-on-insulator (SOI) substrate, a carbon doped oxide, a silicon nitride, a display substrate such as a liquid crystal display (LCD), a plasma display, an electro luminescence (EL) lamp display, a solar array, solar panel, a light emitting diode (LED) substrate, a patterned or non-patterned semiconductor wafer, glass, sapphire, or any other materials such as metals, metal alloys, and other conductive materials.

While not shown, it is contemplated that the substrate 200 may include other structures or features at least partially formed therein. For example, in some implementations, a feature such as a via, a trench, a dual damascene feature, high aspect ratio feature, or the like, may be formed within the substrate through any suitable process or processes, such as an etch process.

In some implementations, a gate dielectric layer (not shown), such as silicon dioxides, carbon doped silicon oxides, or silicon germanium oxides, may be formed on the exposed surface of the channel portion 202. Alternatively, the gate dielectric layer may include high-k dielectric materials having a dielectric value greater than about 3.9. Suitable materials for the gate dielectric layer may include, but are not limited to hafnium oxide, hafnium silicon oxide, hafnium silicon oxynitride, hafnium aluminum oxide, aluminum oxide, tantalum pentoxide, titanium dioxide, zirconium oxide, hafnium zirconium oxide, lanthanum oxide, yttrium oxide, and their aluminates and silicates. The gate dielectric layer may be other suitable materials such as titanium aluminum alloy, tantalum aluminum alloy, titanium nitride, titanium silicon nitride, titanium aluminum nitride, tantalum nitride, tantalum silicon nitride, hafnium nitride, hafnium silicon nitride, hafnium dioxide-alumina alloy, aluminum nitride, or a combination thereof. The gate dielectric layer may have a thickness of about 0.5 nm to about 5 nm, for example 2 nm. Depending upon the material of the layer to be formed, a suitable process, such as atomic layer deposition (ALD) techniques, wet or dry thermal oxidation process, chemical vapor deposition (CVD) techniques, plasma enhanced chemical vapor deposition (PECVD) techniques, physical vapor deposition (PVD) techniques, or combinations thereof, may be used to form the gate dielectric layer.

At block 104, a sacrificial gate 204 is formed over the channel portion 202, as shown in FIG. 2A. The sacrificial gate 204 may be formed by depositing and patterning a layer (or stack of layers) of gate material using suitable lithography and etching until a predetermined size of the sacrificial gate 204 is achieved. The gate material may be comprised of a conductive material such as polysilicon. The sacrificial gate 204 may be made larger than the intended size of the final gate. In one implementation, the sacrificial gate 204 may have a length “L” of about 1 nanometers (nm) to about 20 nm, such as about 2 nm to about 10 nm, for example 3 nm, a width “W” of about and a thickness of about 2 nm to about 80 nm, such as about 5 nm to about 40 nm, for example 7 nm, and a thickness of about 1 nm to about 10 nm, for example 5 nm.

At block 106, the sacrificial gate 204 is patterned and etched to form a PMOS transistor 206 and an NMOS transistor 208 which are separated by a cavity 210, as shown in FIG. 2B. As will be discussed in the subsequent block below, ions or impurities will be implanted into regions of the channel portion 202 not blocked by the sacrificial gate 204 to form source/drain regions for both the PMOS transistor 206 and NMOS transistor 208. Upon completion of the method 100, the PMOS transistor 206 and NMOS transistor 208 will each have a source region and a drain region, with the source region of the PMOS transistor 206 being immediately adjacent to, or butting the drain region of the NMOS transistor 208, for example. While only a single NMOS and PMOS transistor pair are illustrated, those skilled in the art will understand that the same structures are concurrently formed using the same process for many different transistor pairs on an integrated circuit die, and on many different die within a wafer (substrate).

At block 108, a spacer layer 212 is formed in a conformal manner over the exposed surfaces of the remaining sacrificial gates 204a, 204b and the channel portion 202, including side walls of the cavities 210 formed between the remaining sacrificial gates 204a, 204b, as shown in FIG. 2C. The spacer layer 212 may be comprised of a nitride material, such as silicon nitride. In one implementation, the spacer layer 212 may have a thickness of about 0.5 nm to about 3 nm, for example 1 nm. The spacer layer 212 may be formed by any suitable deposition technique such as a chemical vapor deposition (CVD), a physical vapor deposition (PVD), atomic layer deposition (ALD), or high density plasma CVD.

At block 110, a conformal blanket deposition of a hardmask 214 is provided onto the substrate 200 to cover exposed surfaces of the spacer layer 212 and fill the cavities formed between the remaining sacrificial gates 204a, 204b, as shown in FIG. 2D. The hardmask 214 may be formed to a thickness of about 2 nm to about 25 nm, for example about 7 nm, which may vary depending upon the sacrificial gate. The excess hardmask 214 may be optionally removed using a planarization process, such as a chemical mechanic polishing (CMP). The hardmask 214 may be comprised of oxides, nitrides, or a combination thereof. In one implementation, the hardmask is an oxide (e.g., SiO₂). The hardmask 214 may be deposited using any suitable technique such as CVD, plasma enhanced CVD (PECVD), atomic or molecular layer deposition (ALD or MLD), spin on dielectric (SOD) or some combination of these techniques.

At block 112, n-type source/drain regions of the NMOS transistor 208 are exposed by a lithography process. Specifically, the lithography process selectively removes a portion of the hardmask 214 to only expose the spacer layer 212 adjacent opposite sides of a remaining sacrificial gate, for example the remaining sacrificial gate 204b, where source/drain regions are to be formed, as shown in FIG. 2E. That is, the spacer layer 212 covering exposed surfaces of the remaining sacrificial gate 204b and the channel portion 202 adjacent the remaining sacrificial gate 204b are exposed, while the hardmask 214 covering the PMOS transistor 206 remains substantially intact upon lithography process is completed. The n-type source/drain regions of the NMOS transistor 208 may be exposed by patterning a mask layer (not shown) and anisotropically etching the hardmask 214 using the mask layer such that the spacer layer 212 adjacent opposite sides of the remaining sacrificial gate 204b are exposed. The mask layer may have a mask window sized sufficiently to mask the PMOS transistor 206. An etchant may be chosen with a high etch selectivity to oxides (i.e., hardmask 214) over nitrides (i.e., the spacer layer 212), allowing the spacer layer 212 to act as an etch stop. It is contemplated that etching through the hardmask 214 may be accomplished through various wet etch (e.g., in hydrofluoric acid, such as contained in a standard buffered oxide etch, or orthophosphoric acid) or dry etch (e.g., reactive-ion etch (RIE)) techniques.

While an NMOS first scheme (i.e., exposing NMOS transistor 208 first) is discussed herein, a PMOS first scheme is also contemplated. NMOS first scheme may be advantageous in some applications because for n-type contacts low resistance is achieved easier and the process will only be minimally affected by the thermal budget for subsequent p-type doping. PMOS first scheme may also be used in cases where channel materials use pure germanium or the concentration of germanium in silicon above about 30%, for example about 45% or more, or channel materials use a group III-V semiconductor compound.

At block 114, after the NMOS transistor 208 is exposed, an ion implantation process (a beam of ion dopants represented by arrow “D”) is performed to form n-type source/drain regions of the NMOS transistor 208, as shown in FIG. 2F. The phrase “source/drain regions” is used herein to describe a region that may serve as either a source or drain. The source/drain region may include heavily doped source/drain regions and lightly doped source/drain extension regions extending out of the heavily doped source/drain regions, either vertically or horizontally. The source/drain regions and source/drain extension regions may extend a limited extent into the surface of sacrificial gate 204b and the surface of regions adjacent opposite sides of the remaining sacrificial gate 204b. It is understood that a source/drain region may function as a source or a drain depending upon how it is interconnected with subsequent metallization. Therefore, an n-type source region, for example the n-type source region 216b (FIG. 2G), may be connected to a ground contact to complete a simple inverter. The source/drain regions are formed from impurities or dopants of a conductivity type, e.g., n-type or p-type that is opposite to the conductivity type of the substrate.

Various types of dopants may be used to form the source region, the drain region, and the extension regions. For NMOS transistors, n-type dopants may be used. For example, atomic or molecular ions containing Group V elements, such as phosphorous (P), may be provided in an ion source of an ion implanter and implanted into the NMOS transistor 208 not covered by the hardmask 214. Alternatively, other types of n-type dopants containing arsenic, selenium, or tellurium, or any other atomic or molecular n-type dopants may be used. For PMOS transistors, p-type dopants may be used. Examples of p-type dopants may include atomic or molecular ions containing Group III elements, such as boron.

In various implementations, the ion implantation process may be performed at a temperature range of about −220° C. to about 550° C., for example about −200° C. to about 250° C. Low temperature ion implantation leads to a higher degree of amorphization of the structure, and formation of less defects or residual damages during subsequent anneal. Thus, a higher concentration of the dopants implanted into the substrate may be activated. Upon ion implantation process, the n-type source region 216b and n-type drain region 216a (as well as source/drain extension regions) may be lightly doped (n⁺) or heavily doped (n⁺⁺). In one implementation, the n-type source region 216b and n-type drain region 216a are heavily doped. The term “heavily doped” described in this disclosure refers to a dopant or impurity concentration above about 1×10¹⁹/cm³, while the term “lightly doped” described in this disclosure refers to a dopant or impurity concentration less than about 1×10¹⁵/cm³. One skilled artisan in the art will recognize, however, that heavily doped is a term of art that depends upon the specific device type, technology generation, minimum feature size, and the like. It is intended, therefore, that the term be interpreted in light of the technology being evaluated and not be limited to the described implementations.

The dopants may be implanted at an energy of about 1 keV to about 200 keV. The ion implantation process may be performed vertically, or tilted toward the vertical sidewalls of the remaining sacrificial gate 204b at an angle of about 5° to about 45° to provide for greater lateral penetration beneath the sacrificial gate 204b. In some implementations, in order to physically separate the n⁺⁺ drain region 216a of the NMOS transistor 208 from the p⁺⁺ drain region of the PMOS transistor 206 to be formed right next to the n⁺⁺ drain region 216a, the substrate 200 may be tilted so that the laser incidence vector is about 5° off normal incidence away from the hardmask 214 edge. In one implementation, the source/drain regions of the NMOS transistor 208 are implanted with phosphorus ions at a temperature of about −100° C. and an energy of the phosphorus ion implant about 2 keV, with a tilting angle of about 45° with respect to the vertical sidewalls of the gate, for example the sacrificial gates 204b. The resulting dose of phosphorus ion implant is heavily doped.

The relatively high dose and energy of the n-type dopant ion implant in the NMOS transistor 208 results in the remaining sacrificial gate 204b and regions adjacent opposite sides of the remaining sacrificial gate 204b containing n-type dopant ions at or near the surface, and also results in an amorphized, or at least a partially amorphized sacrificial gate 204b and amorphized regions adjacent opposite sides of the remaining sacrificial gate 204b, at or near the surface of the NMOS transistor 208. Amorphous implant regions allow the dopants in the source/drain regions and source/drain extension regions to be activated at lower temperatures (e.g., lower than about 600° C.). In some implementations, ions of Groups III, IV, V, or VI dopants may be co-implanted with the phosphorus ions to result in an amorphous layer with higher than solid solubility concentration. For example, silicon or germanium dopant ions may be co-implanted with the n-type dopant ions. In one implementation, germanium ions are co-implanted with phosphorus ions.

While source/drain regions of the NMOS transistor and the PMOS transistor are being described as doped (lightly or heavily doped), in some implementations of the present disclosure the source/drain regions, part of the source/drain regions, or part of the contact regions could be also undoped, or at least undoped at first. In such a case, a shallow coating of doping material may be applied to the source/drain regions, and does not need to extend the entire depth of the source/drain regions. For example, the shallow coating of doping material may extend about 1% to about 25%, for example about 2% to about 10%, of the entire depth of the source/drain regions. The shallow coating need only extend enough to ensure low contact resistivity and overall resistivity to the gate, allowing carriers to be injected into the gate region. The shallow coating of doping material may have the same or different conductivity type than the NMOS transistor or the PMOS transistor. The layer can be formed by amorphizing implantation of various atoms, doping or non-doping (amorphous regions), combined with implants of doping atoms (non-amorphous regions). Instead of implanting for amorphization it is also possible to deposit amorphous material of the same composition or different composition but from a band alignment perspective favorable, meaning not exhibiting a barrier for the respective carriers (electrons of holes), onto the substrate material on top of the source/drain region, or contact region, which can be doped or not doped, or doped by an implant but with shallower range than the amorphous layer. This approach is to allow for junctionless FET's and include deposited amorphous layers.

At block 116, an anneal process is performed to recrystallize amorphized regions of the NMOS transistor 208 implanted with dopants (i.e., the sacrificial gate 204b, n-type source region 216b and n-type drain region 216a of the NMOS transistor 208), as shown in FIG. 2G. Since the regions implanted with dopants are in amorphous state, the melting point of amorphous regions is relatively lower than that of non-implanted regions, which are in crystalline state. For example, if the amorphized regions were made of silicon (melting point of about 141° C.) or silicon-based material such as silicon germanium (melting point of about 1300° C.), a temperature of 1200° C. or more may suffice to melt the amorphized portion at or near the surface of the implanted regions because amorphous silicon melts at a temperature lower than crystalline silicon, while the bulk of the underlying structure remains crystalline and does not melt. The melting of amorphized regions therefore employs a laser energy that is lower, for example about 10% or 20% lower as needed for melting crystalline regions, which may vary depending upon stoichiometry. With the right annealing temperature, the anneal process can selectively or preferentially melt and recrystallize the amorphized, implanted regions over the non-implanted regions. Upon recrystallization, the crystalline lattice structure is restored and dopants in the implanted regions are properly distributed and electronically activated, forming heavily doped source/drain regions of the NMOS transistor 208. The surfaces needed for output contact are superactive and the adjacent p-type regions, gates etc., are not affected. While laser energy is discussed herein, it is contemplated that melting of amorphized regions may be done by a thermal annealing process, such as a rapid thermal annealing or spike annealing process, or any other suitable process.

It is understood that a source/drain region may function as a source or a drain depending upon how it is interconnected with subsequent metallization. Some n-type source/drain regions may be connected to some n-type source/drain regions, some p-type source/drain regions may be connected to some p-type source/drain regions, and/or some n-type source/drain regions may be connected to some p-type source/drain regions, with some source/drain regions end without connection. In addition, any of the source/drain regions of the NMOS or PMOS transistor may be electrically connected to a ground contact or a power supply voltage contact. For example, in some implementations an n-type source region, for example the n-type source region 216b, may be electrically connected to a ground contact, while a p-type source region, for example the p-type source region 220a (FIG. 2K), may be electrically connected to a power supply voltage (VDD) contact.

In various implementations, the anneal process can be carried out using laser anneal processes, spike anneal processes, rapid thermal anneal processes, and/or furnace anneal processes. In one implementation of the present disclosure, the n-type dopants within amorphized implant regions are activated using a laser anneal process. The laser anneal process may be a dynamic surface anneal (DSA) process. Laser anneal processes may deliver a constant energy flux from an energy source to a small region on the target surface of the substrate (i.e., the NMOS transistor 208) while the substrate is translated, or scanned, relative to the energy (or vice versa) delivered to the small region. The energy source may deliver electromagnetic radiation energy to perform the annealing process at desired regions of the substrate. Typical sources of electromagnetic radiation energy may include, but are not limited to, an optical radiation source, an electron beam source, an ion beam source, and/or a microwave energy source, any of which may be monochronistic or polychronistic and may have any desired coherency. In one implementation, the energy source is an optical radiation source using one or more laser sources. The lasers may be any type of laser such as gas laser, excimer laser, solid-state laser, fiber laser, semiconductor laser etc., which may be configurable to emit light at a single wavelength or at two or more wavelengths simultaneously.

In some implementations, the laser anneal process may use lasers having a wavelength of between about 10 nm and about 2,000 nm, such as from 190 nm to 1064 nm, for example 365 nm to 536 nm. The lasers may be delivered on a desired region of the NMOS transistor 208 at short pulses, such as on the order of nanosecond or even millisecond. Nanosecond or millisecond annealing process is believed to enable precise control of the placement of dopants (e.g., phosphorus) in the crystalline lattice structure while limiting diffusion of the dopants to an extent that exceeds manufacturing tolerances and therefore deactivates the dopants. Very fast heating of the amorphized, implanted region is advantageous in some applications as it minimizes substrate damage due to thermal stress while achieving melting of the amorphized region before it crystallizes. In some implementations, nanosecond pulsed lasers having a pulse duration from a few nanoseconds to about 200 nanoseconds, such as between 10 nsec and 100 nsec, for example 20 nsec, may be used to melt the implanted regions. The energy delivered in each pulse may be between about 10 mJ/cm² and 1.0 J/cm², such as between about 100 mJ/cm² and about 500 mJ/cm², for example about 300 mJ/cm². The repetition rate of the energy pulse may be between about 1 kHz and about 1 MHz, such as between about 10 kHz and about 250 kHz, for example about 50 kHz to about 100 kHz. The laser anneal process may be repeated about 20 times to about 100 times, for example about 50 times. The pulsing of lasers allows complete recrystallization via melt and superactivation at a lower thermal budget as single pulse anneal.

At block 118, a conformal blanket deposition of a hardmask 218 is provided onto the substrate 200 to cover the NMOS transistor 208, as shown in FIG. 2H. The hardmask 218 may be formed to a thickness a thickness of about 2 nm to about 25 nm, for example about 7 nm, which may vary depending upon the sacrificial gate 204b. The deposited hardmask 218 is then planarized using a suitable technique such as chemical-mechanical planarization (CMP) so that the deposited hardmask 218 is about the same height as the hardmask 214 covering the PMOS transistor 206. The hardmask 218 may be comprised of oxides, nitrides, or a combination thereof. In one implementation, the hardmask is an oxide (e.g., SiO₂). The hardmask 218 may be deposited using any suitable technique such as CVD, plasma enhanced CVD (PECVD), atomic or molecular layer deposition (ALD or MLD), spin on dielectric (SOD) or some combination of these techniques.

At block 120, the previously deposited hardmask 214 covering the PMOS transistor 206 is removed using a lithography process to expose source/drain regions of the PMOS transistor 206, as shown in FIG. 2I. Similar to block 112 discussed above, the lithography process selectively removes a portion of the hardmask 214 to only expose the spacer layer 212 adjacent opposite sides of a sacrificial gate, for example the remaining sacrificial gate 204a, where source/drain regions are to be formed. That is, the spacer layer 212 covering exposed surfaces of the remaining sacrificial gate 204a and the channel portion 202 adjacent the remaining sacrificial gate 204a are exposed, while the hardmask 218 covering the NMOS transistor 208 remains substantially intact upon lithography process is completed. The p-type source/drain regions of the PMOS transistor 206 may be exposed by patterning a mask layer (not shown) and anisotropically etching the hardmask 214 using the mask layer such that the spacer layer 212 adjacent opposite sides of the remaining sacrificial gate 204a are exposed. The mask layer may have a mask window sized sufficiently to mask the NMOS transistor 208. An etchant may be chosen with a high etch selectivity to oxides (i.e., hardmask 218) over nitrides (i.e., the spacer layer 212), allowing the spacer layer 212 to act as an etch stop. It is contemplated that etching through the hardmask 214 may be accomplished through various wet etch (e.g., in hydrofluoric acid, such as contained in a standard buffered oxide etch, or orthophosphoric acid) or dry etch (e.g., reactive-ion etch (RIE)) techniques.

At block 122, after the PMOS transistor 206 is exposed, an ion implantation process (a beam of ion dopants represented by arrow “D”) is performed to form p-type source/drain regions of the PMOS transistor 206, as shown in FIG. 2J. Similarly to NMOS transistor 208, the source/drain region may include heavily doped source/drain regions and lightly doped source/drain extension regions extending out of the heavily doped source/drain regions, either vertically or horizontally. The source/drain regions and source/drain extension regions may extend a limited extent into the surface of remaining sacrificial gate 204a and the surface of regions adjacent opposite sides of the sacrificial gate 204a. It is understood that a source/drain region may function as a source or a drain depending upon how it is interconnected with subsequent metallization. The source/drain regions are formed from impurities or dopants of a conductivity type, e.g., n-type or p-type that is opposite to the conductivity type of the substrate. Various types of dopants may be used to form the source region, the drain region, and the extension regions. For PMOS transistors, p-type dopants may be used. Examples of p-type dopants may include atomic or molecular ions containing Group III elements, such as boron.

In various implementations, the ion implantation process may be performed at a temperature range of about −220° C. to about 550° C., for example about −200° C. to about 250° C. Low temperature ion implantation leads to a higher degree of amorphization of the structure, and formation of less defects or residual damages during subsequent anneal. Thus, a higher concentration of the dopants implanted into the substrate may be activated. Upon ion implantation process, the p-type source region 220a and p-type drain region 220b (as well as source/drain extension regions) may be lightly doped (p⁺) or heavily doped (p⁺⁺). In one implementation, the p-type source region 220a and p-type drain region 220b are heavily doped. The dopants may be implanted at an energy of about 1 keV to about 200 keV.

The ion implantation process may be performed vertically, or tilted toward the vertical sidewalls of the sacrificial gate 204a at an angle of about 5° to about 45° to provide for greater lateral penetration beneath the sacrificial gate 204a. In some implementations, the substrate 200 may be tilted during the ion implantation to prevent mixing of the p-type drain region of the PMOS transistor 206 with the previously formed n-type source region of the NMOS transistor 208. For example, the laser incidence vector may be about 5° off normal incidence away from the hardmask 218 edge to leave a minimal gap between the p-type drain region 220b and the previously formed n⁺⁺ drain region 216a right next to the p-type drain region 220b. In one implementation, the source/drain regions of the PMOS transistor 206 are implanted with boron ions at a temperature of about −100° C. and an energy of the boron ion implant about 0.3 keV, with a tilting angle of about 45° with respect to the vertical sidewalls of the gate, for example sacrificial gates 204a. The resulting dose of phosphorus ion implant is heavily doped.

The relatively high dose and energy of the p-type dopant ion implant in the PMOS transistor 206 results in the remaining sacrificial gate 204a and regions adjacent opposite sides of the remaining sacrificial gate 204a containing p-type dopant ions at or near the surface, and also results in an amorphized, or at least a partially amorphized sacrificial gate 204a and amorphized regions adjacent opposite sides of the remaining sacrificial gate 204a, at or near the surface of the PMOS transistor 206. Amorphous implant regions allow the dopants in the source/drain regions and source/drain extension regions to be activated at lower temperatures (e.g., lower than about 600° C.). In some implementations, ions of Groups III, IV, V, or VI dopants may be co-implanted with the boron ions to result in an amorphous layer with higher than solid solubility concentration. For example, silicon or germanium dopant ions may be co-implanted with the p-type dopant ions. In one implementation, germanium ions are co-implanted with boron ions.

At block 124, an anneal process is performed to recrystallize amorphized regions of the PMOS transistor 206 implanted with dopants (i.e., the sacrificial gate 204a, p-type source region 220a and p-type drain region 220b of the PMOS transistor 206), as shown in FIG. 2K. Since the regions implanted with dopants are in amorphous state, the melting point of amorphous regions is relatively lower than that of non-implanted regions, which are in crystalline state. As discussed previously, with the right annealing temperature, the anneal process can selectively or preferentially melt and recrystallize the amorphized, implanted regions over the non-implanted regions. Particularly, the difference in melt temperature to crystalline regions can prevent any mixing at the interface of the n⁺⁺ to p⁺⁺ regions. Upon recrystallization, the crystalline lattice structure is restored and dopants in the implanted regions are properly distributed and electronically activated, forming heavily doped source/drain regions of the PMOS transistor 206. The surfaces needed for output contact are superactive and the adjacent n-type regions, gates etc., are not affected. As can be seen, the p-type drain region 220b of the PMOS transistor 206 is directly connected, abutted against, or in physical contact with the n-type source region 216b of the NMOS transistor 208.

The anneal process may be any of the suitable anneal process as discussed above with respect to block 116. In one implementation of the present disclosure, the p-type dopants within amorphized implant regions are activated using a laser anneal process. In some implementations, the laser anneal process may use lasers having a wavelength of between about 10 nm and about 2,000 nm, such as from 190 nm to 1064 nm, for example 365 nm to 536 nm. The lasers may be delivered on a desired region of the PMOS transistor 206 at short pulses, such as on the order of nanosecond or even millisecond. Nanosecond or millisecond annealing process enables precise control of the placement of dopants (e.g., borons) in the crystalline lattice structure while limiting diffusion of the dopants to an extent that exceeds manufacturing tolerances and therefore deactivates the dopants. In some implementations, nanosecond pulsed lasers having pulse duration from a few nanoseconds to about 200 nanoseconds, such as between 10 nsec and 100 nsec, for example 20 nsec, may be used to melt the implanted regions. The energy delivered in each pulse may be between about 10 mJ/cm² and 1.0 J/cm², such as between about 100 mJ/cm² and about 500 mJ/cm², for example about 300 mJ/cm². The repetition rate of the energy pulse may be between about 1 kHz and about 1 MHz, such as between about 10 kHz and about 250 kHz, for example about 50 kHz to about 100 kHz. The laser anneal process may be repeated about 20 times to about 100 times, for example about 50 times. The pulsing of lasers allows complete recrystallization via melt and superactivation at a lower thermal budget as single pulse anneal.

At block 126, the hardmask 218 covering the NMOS transistor 208 is removed to expose both PMOS transistor 206 and NMOS transistor 208, with the p-type drain region 220b of the PMOS transistor 206 directly connecting, abutting against, or in physical contact with the n-type source region 216b of the NMOS transistor 208, as shown in FIG. 2L. An etchant may be chosen with a high etch selectivity to oxides (i.e., hardmask 218) over nitrides (i.e., the spacer layer 212), allowing the spacer layer 212 to act as an etch stop. It is contemplated that etching through the hardmask 218 may be accomplished through any suitable etching technique such as wet etch (e.g., in hydrofluoric acid, such as contained in a standard buffered oxide etch, or orthophosphoric acid) or dry etch (e.g., reactive-ion etch (RIE)) techniques.

At block 128, after both PMOS transistor 206 and NMOS transistor 208 are exposed, a conformal blanket deposition of dielectric material, such as silicon oxide (oxide), silicon nitride (nitride), or the like, may be formed onto the substrate 200 to fill the cavities or trenches between and adjacent the PMOS transistor 206 and NMOS transistor 208 until a desired thickness is achieved, as shown in FIG. 2L. Filling the cavities or trenches with the dielectric material suppress leakage current or provides electrical isolation between neighboring devices of opposite-type (i.e., PMOS and NMOS transistors 206, 208). The dielectric material may be deposited by any suitable deposition technique such as a chemical vapor deposition (CVD), a physical vapor deposition (PVD), atomic layer deposition (ALD), or high density plasma CVD.

At block 130, a planarization process, such as CMP is performed to polish the substrate to remove the dielectric material from the active regions (i.e., PMOS transistor 206 and NMOS transistor 208), thereby exposing a top surface of the sacrificial gates 204a, 204b, as shown in FIG. 2M.

At block 132, the sacrificial gates 204a, 204b of PMOS transistor 206 and NMOS transistor 208 are removed respectively using a selective etch process, forming gate trenches 222, 224 in the PMOS transistor 206 and NMOS transistor 208 where the sacrificial gates 204a, 204b were located, as shown in FIG. 2N. In cases where the sacrificial gates 204a, 204b were made of polysilicon, the selective etch process removes only polysilicon such that the channel portion 202 remains substantially intact after the selective etch process. The selective etch process may use any suitable wet etchants or dry etchants, depending upon the application and the gate material to be removed. In either case, the etchants should exhibit a high etch rate (e.g., 100:1 or above) on the sacrificial gates 204a, 204b with a very low or zero etch rate on the channel portion 202 and other features of the PMOS transistor 206 and NMOS transistor 208.

At block 134, the gate trench in the PMOS transistor 206 and the gate trench in the NMOS transistor 208 are each filled with p-type metal gate 226 and n-type metal gate 228, respectively, as shown in FIG. 2O. The p-type metal gate 226 and n-type metal gate 228 may be formed to cover at least exposed surfaces of the spacer layer 212 in the gate trenches 222, 224. That is, portions of the sacrificial gates 204a, 204b that were removed are replaced with p-type metal gate 226 and n-type metal gate 228, respectively.

In some implementations, the p-type metal gate 226 and n-type metal gate 228 may form around a top surface, a bottom surface, and two opposing side surfaces of the channel portion 202 exposed within the gate trenches 222, 224, respectively. The transistor device that utilizes a wrap-around metal gate structure advantageously scales the contact area for a given size and length of the channel portion 202. By surrounding the spacer layer 212 (and thus the channel portion 202), the metal gates 226, 228 can exert more control over the channel portion 202 and better control on and/or off states of the NMOS and PMOS transistors 206, 208, among other things, even in view of short channel effects.

The resulting p-type source/drain regions 220a, 220b and the n-type source/drain regions 216b, 216a are formed on opposite sides of the p-type metal gate 226 and n-type metal gate 228, respectively. The metal gate of the NMOS and PMOS transistors 206, 208 permits or shuts off the current flowing from the source region to the drain region by controlling voltage applied to the metal gate. The p-type metal gate 226 and n-type metal gate 228 may have a thickness suitable to provide the appropriate work function for the semiconductor device being processed. For example, the p-type metal gate 226 and n-type metal gate 228 may each have a thickness of about 10 Angstroms (Å) to several hundred Å, for example about 20 Å to about 100 Å.

In various implementations, the p-type metal gate 226 and n-type metal gate 228 may include a metal, a metal alloy, a metal nitride, a metal silicide, or a metal oxide. In some implementations, the p-type metal gate 226 and n-type metal gate 228 may contain titanium, titanium aluminum alloy, tantalum, tantalum aluminum alloy, titanium nitride, titanium silicon nitride, titanium aluminum nitride, tantalum nitride, tantalum silicon nitride, hafnium nitride, hafnium silicon nitride, aluminum nitride, aluminum oxide, tungsten, platinum, aluminum, ruthenium, molybdenum, other conductive materials, or a combination thereof. It should be appreciated that p-type metal gate 226 and n-type metal gate 228 need not necessarily be a single material, but could comprise a composite stack of thin films using materials discussed herein. In some implementations, the composite stack of p-type metal gate and n-type metal gate may further include a polycrystalline silicon. Depending upon the material of the layer to be formed, a suitable process, such as atomic layer deposition (ALD) techniques, chemical vapor deposition (CVD) techniques, plasma enhanced chemical vapor deposition (PECVD) techniques, physical vapor deposition (PVD) techniques, or combinations thereof, may be used to form the p-type metal gate 226 and n-type metal gate 228.

At block 136, a layer of nitride spacer 230, such as SiₓN_{y}, may be deposited onto the p-type metal gate 226 and n-type metal gate 228 to backfill gate trenches 222, 224, respectively, as shown in FIG. 2P. The nitride spacer 230 may have a thickness relatively thicker than the spacer layer 212. In one implementation, the nitride spacer 230 may have a thickness of about 1 nm to about 10 nm, for example 3 nm to about 5 nm. The nitride spacer 230 may be formed by any suitable deposition technique such as a chemical vapor deposition (CVD), a physical vapor deposition (PVD), atomic layer deposition (ALD), or high density plasma CVD.

At block 138, a conformal blanket deposition of an oxide layer 232, such as silicon oxide (oxide) or the like, may be formed onto the substrate 200 to fill the cavities or trenches between and the PMOS transistor 206 and NMOS transistor 208 and exposed surfaces of the spacer layer 212 until a desired thickness is achieved, as shown in FIG. 2Q. The oxide layer 232 may be deposited by any suitable deposition technique such as thermal, rapid thermal oxidation (RTO), chemical vapor deposition (CVD) or other advanced oxide-grown technology. Thereafter, a planarization process, such as CMP, may be performed to polish and remove excess oxide layer 232. The resulting oxide layer 232 may have a thickness of about 5 nm to about 20 nm, for example 8 nm to about 10 nm.

At block 140, a photolithography and etching are performed to remove a portion of the oxide layer 232 to selectively expose a top surface of the nitride spacer 230 covering the p-type metal gate 226 and n-type metal gate 228, thereby forming the contact openings 234, 236 for the PMOS transistor 206 and NMOS transistor 208, as shown in FIG. 2Q. The contact openings 234, 236 are self-aligned by the nitride spacer 230.

At block 142, an oxide spacer 238 is formed onto the sidewalls of the contact openings 234, 236, as shown in FIG. 2R. The oxide spacer 238 may be formed by depositing a conformal oxide layer on the exposed surface of the substrate 200 through methods including, but not limited to, thermal, rapid thermal oxidation (RTO), chemical vapor deposition (CVD) or other advanced oxide-grown technology. The oxide layer is then etched back to expose the nitride spacer 230 covering the p-type metal gate 226 and n-type metal gate 228, leaving oxide spacer 238 only on sidewalls of the contact openings 234, 236. The etch back process may use anisotropic etch process, such as dry etch, RIE (Reactive Ion Etching), or other plasma etching processes. The oxide spacer 238 may have a thickness of about 0.5 nm to about 2 nm, for example about 1 nm.

At block 144, a selective etch process is performed to remove the nitride spacer 230 exposed within the contact openings 234, 236. The selective etch process removes only the nitride spacer 230 such that the oxide spacer 238 remains substantially intact after the selective etch process. The selective etch process may use any suitable wet etchants or dry etchants, depending upon the application and the material to be removed. In either case, the etchants should exhibit a high etch rate (e.g., 100:1 or above) on the nitride spacer 230 with a very low or zero etch rate on the oxide spacer 238 and other features of the PMOS transistor 206 and NMOS transistor 208.

At block 146, a contact metallization is performed to dispose a metal contact layer 240a, 240b, 240c onto the oxide layer 232, as shown in FIG. 2S. The contact layers 240a, 240b, 240c form interconnects for the PMOS transistor 206 and NMOS transistor 208. For example, the metal contact layer 204b is at least in electrical communication with the p-type drain region of the PMOS transistor and the n-type source region of the NMOS transistor to function as a common output contact for at least the PMOS transistor 206 and NMOS transistor 208, and thus function as one of the output contacts for the device. In some implementations, the metal contact layer, for example the metal contact layer 240b, may be in indirect contact with the p-type drain region 220b of the PMOS transistor and n-type source region 216b of the NMOS transistor. The boundaries of the metal contact layers 240a, 240b, 240c are defined in part by the oxide spacer 238 formed onto the sidewalls of the contact openings 234, 236. The metal contact layer 240a-c may be formed of tungsten, titanium, or molybdenum, or other suitable electrical conductive material.

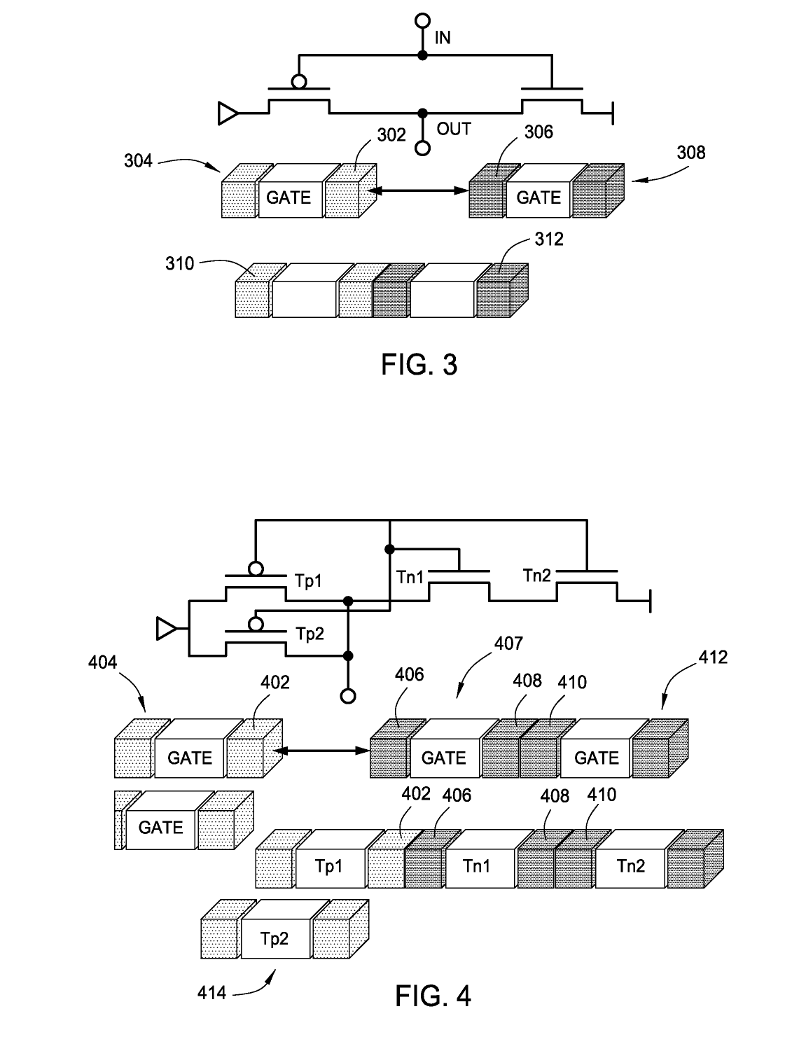

FIG. 3 illustrates a conceptual inverter fabricated to have a p-type drain 302 of a p-type transistor 304 directly connected in series, abutted against, or in physical contact with an n-type drain 306 of an n-type transistor 308 to according to implementations of the present disclosure. The p-type drain 302 and the n-type drain 306 serve as an output contact while an n-type source 310 and a p-type source 312 serve as VDD contact and ground contact, respectively. FIG. 4 illustrates a conceptual NAND gate fabricated according to implementations of the present disclosure. In one implementation as shown, a p-type drain 402 of a first p-type transistor 404 (Tp1) is directly connected in series, abutted against, or in physical contact with an n-type drain 406 of a first n-type transistor 407 (Tn1), which has its n-type source 408 in direct contact with a n-type drain 410 of a second n-type transistor 412. In this implementation, the first p-type transistor 404 (Tp1) is also connected in parallel with a second p-type transistor 414.

Implementations of the present disclosure provide CMOS devices made with FIN transistors and specifically nanowire transistors of node N7, N5, n-type and p-type transistors in inverters, NAND and NOR gates having the common output contact integrated by directly connecting p-type and n-type drain regions and by having the common contact to both these regions. Implementations of the present disclosure can solve problems of integration like photolithography limitations, self alignment, prevention of x-diffusion during super activation and requirements for different MIS/MS contact schemes in a small common contact area. In addition, implementations of the present disclosure can save a significant space as compared to conventional CMOS approaches where n-type and p-type transistor drain regions are completely separated with or without n-well and p-well around them.

While the foregoing is directed to implementations of the present disclosure, other and further implementations of the disclosure may be devised without departing from the basic scope thereof.

1. An integrated circuit, comprising:
a first transistor having a first conductivity type, the first transistor comprising a first gate, an first source region and a first drain region disposed on opposite sides of the first gate; and
a second transistor having a second conductivity type opposite from the first conductivity type of the first transistor, the second transistor comprising a second gate, a second source region and a second drain region disposed on opposite sides of the second gate, wherein the second drain region of the second transistor is abutted against the first drain region of the first transistor.

2. The integrated circuit of claim 1, further comprising:
a common output contact in electrical communication with the first drain region of the first transistor and the second drain region of the second transistor.

3. The integrated circuit of claim 1, wherein the first drain region of the first transistor and the second drain region of the second transistor are heavily doped.

4. The integrated circuit of claim 1, wherein the first drain region of the first transistor comprises a shallow coating layer of doping material and the second drain region of the second transistor comprises a shallow coating layer of doping material, each shallow coating layer extends a depth of the first drain region of the first transistor and the second drain region of the second transistor, and each shallow coating layer has low contact resistivity to the respective first gate and second gate.

5. The integrated circuit of claim 1, wherein the shallow coating layer of doping material comprises amorphous regions and non-amorphous regions, and the non-amorphous regions comprise an implant of doping atoms.

6. The integrated circuit of claim 5, wherein non-amorphous regions are disposed relatively above the amorphous regions.

7. The integrated circuit of claim 1, wherein the first source region of the first transistor is electrically connected to a power supply voltage contact, and the second source region of the second transistor is electrically connected to a ground contact.

8. An integrated circuit, comprising:
a first transistor having a first conductivity type, the first transistor comprising a first gate, an first source region and a first drain region disposed on opposite sides of the first gate;
a second transistor having a second conductivity type opposite from the first conductivity type of the first transistor, the second transistor comprising a second gate, a second source region and a second drain region disposed on opposite sides of the second gate, wherein the p-type drain region of the second transistor is abutted against the n-type drain region of the first transistor; and
an output contact in electrical communication with the first drain region of the first transistor and the second drain region of the second transistor, wherein the first drain region of the first transistor and the second drain region of the second transistor each comprises a heavily doped region.

9. The integrated circuit of claim 8, wherein the first source region of the first transistor is electrically connected to a ground contact and the second source region of the second transistor is electrically connected to a power supply voltage contact.

10. The integrated circuit of claim 8, wherein the heavily doped region has a dopant concentration above about 1×10¹⁹/cm³.

11. The integrated circuit of claim 8, wherein the first drain region of the first transistor and the second drain region of the second transistor each comprises a lightly doped region vertically or horizontally extending out of the heavily doped region, and the lightly doped region has a dopant concentration less than about 1×10¹⁵/cm³.

12. The integrated circuit of claim 8, wherein the output contact is separated from the first drain region of the first transistor and the second drain region of the second transistor by an oxide layer.

13. A method of forming an integrated circuit, comprising:
forming a first transistor having a first conductivity type on a substrate, the first transistor comprising a first gate, an first source region and a first drain region disposed on opposite sides of the first gate;
forming a second transistor having a second conductivity type opposite from the first conductivity type of the first transistor, the second transistor comprising a second gate, a second source region and a second drain region disposed on opposite sides of the second gate, wherein the second drain region of the second transistor is abutted against the first drain region of the first transistor;
covering the second transistor and implanting dopants into the first drain region of the first transistor by tilting the substrate at an angle;
activating implanted dopants in the first drain region, wherein the first drain region is heavily doped with dopants having the first conductivity type;
covering the first transistor and implanting dopants into the second drain region of the second transistor by tilting the substrate at an angle;
activating implanted dopants in the second drain region, wherein the second drain region is heavily doped with dopants having the second conductivity type; and
forming an output contact layer over the first drain region of the first transistor and the second drain region of the second transistor, wherein the output contact is in electrical communication with the first drain region of the first transistor and the second drain region of the second transistor.

14. The method of claim 13, wherein the first drain region and the second drain region are activated by an annealing process using a laser energy having a pulse duration on the order of nanosecond or millisecond.

15. The method of claim 13, wherein the first drain region and the second drain region are activated by a thermal annealing process.

16. The method of claim 13, wherein the first drain region and the second drain region each has a dopant concentration above about 1×10¹⁹/cm³.

17. The method of claim 13, wherein the dopants are implanted into the first and second drain regions by tilting the substrate at an angle of about 45° with respect to vertical sidewalls of the first and second gates, respectively.

18. The method of claim 13, further comprising:
forming a shallow coating of doping material onto the first drain region and the second drain region, respectively, wherein the shallow coating layer has low contact resistivity to the respective first gate and second gate.

19. The method of claim 18, wherein the shallow coating layer of doping material comprises amorphous regions and non-amorphous regions.

20. The method of claim 18, wherein the shallow coating of doping material has the same or different conductivity type than the conductivity type of the first transistor or the second transistor.
